(19) United States
(12) Patent Application Publication
(10) Pub. No.: US 2009/0020832 A1
(43) Pub. Date: Jan. 22, 2009

(54) Semiconductor Devices and the Manufacture Thereof

(75) Inventors: Steven T. Peake, Warrington (GB); Keith A. Jaggers, Poynton (GB)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/574,015

(22) PCT Filed: Aug. 18, 2005
(86) PCT No.: PCT/IB2005/052725

§ 371 Date: Feb. 20, 2007

(30) Foreign Application Priority Data
Aug. 20, 2004 (EP) 0418573.2

(51) Int. Cl. H01L 29/78; H01L 21/22

(52) U.S. Cl. 257/408; 438/542; 257/E29.266; 257/E21.135

(57) ABSTRACT

A power semiconductor device includes a semiconductor body (10), the semiconductor body comprising source and drain regions (13, 14, 14a) of a first conductivity type, and a channel-accommodating region (15) of a second, opposite conductivity type which separates the source and drain regions. The drain region comprises a drain contact region (14a) and a drain drift region (14) which extends from the drain contact region to the channel accommodating region (15), the drain drift region having a doping profile which decreases substantially exponentially from its interface (19) with the drain contact region, to its interface (21) with the channel-accommodating region. This configuration provides lower switching losses relative to a device with a uniform or linear drain doping profile.

The present invention relates to transistor semiconductor devices, and more particularly to such devices having a vertical configuration. It also concerns the manufacture of such devices.

Such devices are known having source and drain regions separated by a channel-accommodating region. Typically, the drain region comprises a drain contact region overlaid by a relatively low doped drain drift region, and the drain drift region is uniformly doped.

With a view to providing a power transistor device with a low on-state resistance and high voltage blocking capability, U.S. Pat. No. 5,637,898 discloses a device having a linearly graded doping concentration profile decreasing in a direction from the drain contact region to the channel-accommodating region.

The present invention provides a semiconductor device including a semiconductor body, the semiconductor body comprising source and drain regions of a first conductivity type, and a channel-accommodating region of a second, opposite conductivity type which separates the source and drain regions, the device further comprising a gate which extends adjacent respective portions of the source, drain and channel-accommodating regions and is separated therefrom by a gate insulating layer, wherein the drain region comprises a drain contact region, and a drain drift region which extends from the drain contact region to the channel-accommodating region, the drain drift region having a doping profile which decreases substantially exponentially from its interface with the drain contact region to its interface with the channel-accommodating region.

In such a structure, the amount of dopant in the region of the drain drift region close to the interface with the channel-accommodating region is lower than that of a device with a uniform or linear doping profile having the same total amount of dopant in the drain drift region. This results in the device having lower switching losses, as the depletion region will be wider reducing its contribution to the gate-drain capacitance of the device.

Furthermore, in a trench-gate device, the reduced level of doping near the trench corners reduces the electric field created at the trench corners. This increases the device lifetime, as the gate insulating layer is subjected to fewer energetic electrons created by high electric fields in the depletion region at the drift region/channel-accommodating region interface.

Preferably, the doping of the drain drift region at a distance X from the channel-accommodating region is approximately equal to A^{BX}, where A and B are constants.

In a preferred embodiment, a portion of the gate insulating layer between the gate and the drain drift region is thicker than a portion between the gate and the channel-accommodating region.

The device may include field shaping means, such as a field plate electrode for example, which extends adjacent the drain drift region, and is separated therefrom by an insulating layer. This electrode may be connected to the gate, and may preferably be integrally formed with the gate. Such field shaping means may be provided to give a RESURF effect, which may be enhanced by the exponential doping profile of the drift region.

The invention further provides a method of manufacturing a device according to the invention, wherein the thermal budget of processing of the device causes dopant to diffuse out of the drain contact region into the drain drift region to form the substantially exponential doping profile in the drift region. In this method, the drain contact region is doped with a dopant having a relatively high coefficient of diffusion such that it diffuses out during processing, creating the desired profile across the drift region.

Phosphorus is a preferred example of a suitable dopant for use in this method. Preferably, prior to said out-diffusion the drain contact region comprises phosphorus atoms at a concentration around or greater than 4.8×10¹⁹ atoms/cm³. This results, in the finished device, in a drain contact region of low resistivity, significantly reducing its contribution to the specific on-resistance of the device.

Prior to the out-diffusion from the drain contact region, the drain drift region is uniformly doped, at a low level relative to that of the drain contact region. Alternatively, the drift region may be non-uniformly doped, in a manner that complements the distribution of dopant resulting from out-diffusion from the drain contact region, so the finished device has the desired exponential drift doping profile.

The invention also provides a method of manufacturing a device of the invention, the method including the steps of providing a semiconductor body comprising a highly doped drain contact region, and forming thereon by epitaxial growth a layer having a doping profile which decreases substantially exponentially from its interface with the drain contact region to its top surface. During epitaxial growth, the doping concentration in the material being deposited may be closely controlled to provide the desired profile.

Prior art devices and embodiments of the invention will now be described by way of example and with reference to the accompanying schematic drawings, wherein:

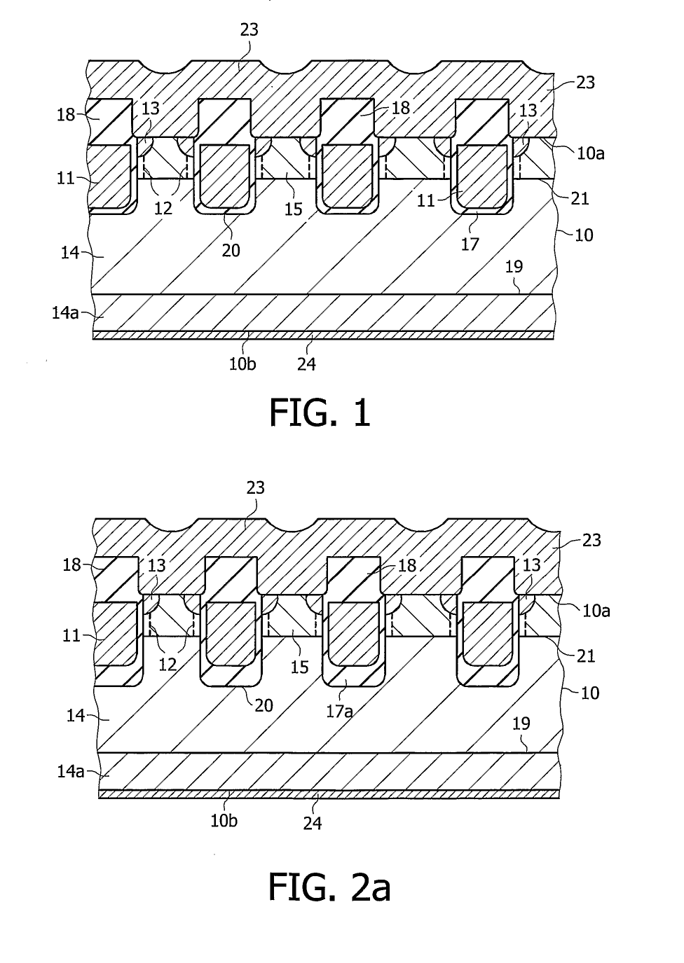

FIG. 1 shows a cross-sectional view of transistor cell areas of a trench-gate semiconductor device according to a first embodiment of the invention;

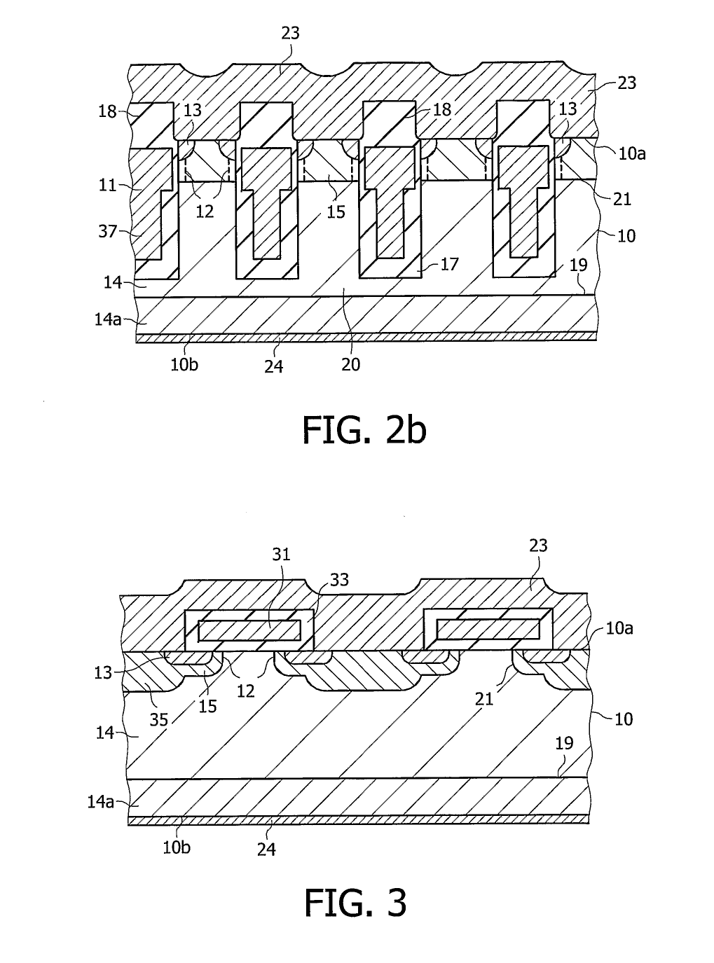

FIGS. 2a and 2b show cross-sectional views of transistor cell areas of trench-gate semiconductor devices according to second and third embodiments of the invention;

FIG. 3 shows a cross-sectional view of transistor cell areas of a planar-gate semiconductor device according to a third embodiment of the invention;

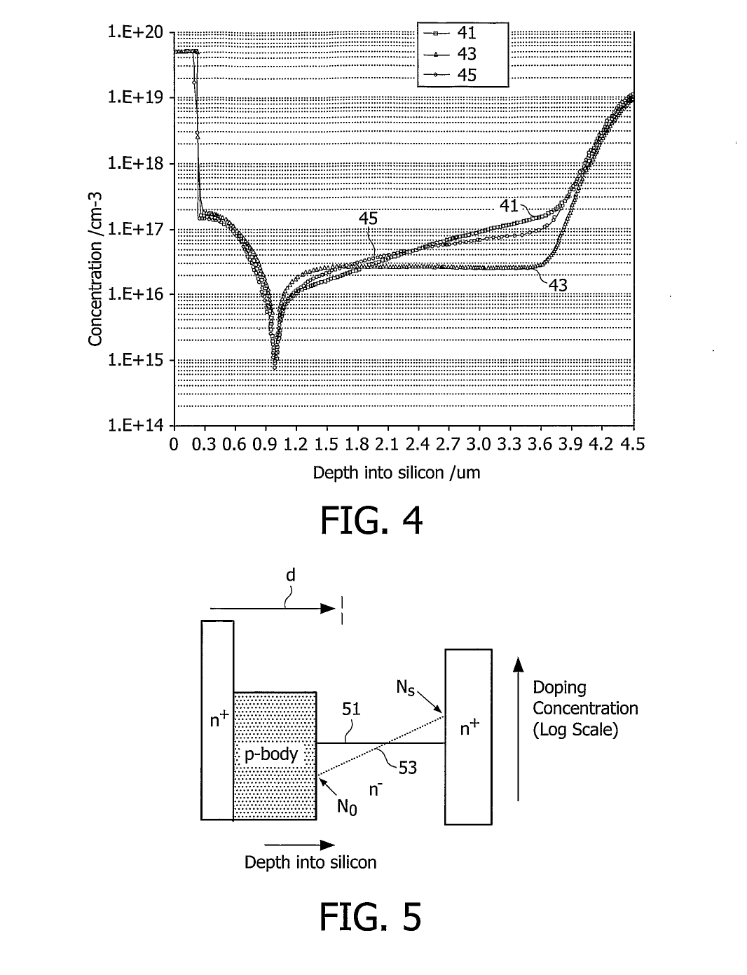

FIG. 4 shows plots of doping concentration against depth into a semiconductor body for semiconductor devices of the prior art and according to an embodiment of the invention;

FIG. 5 shows a bar graph representing doping levels at different depths in the semiconductor body of a trench-gate semiconductor device of the prior art, and according to an embodiment of the invention; and

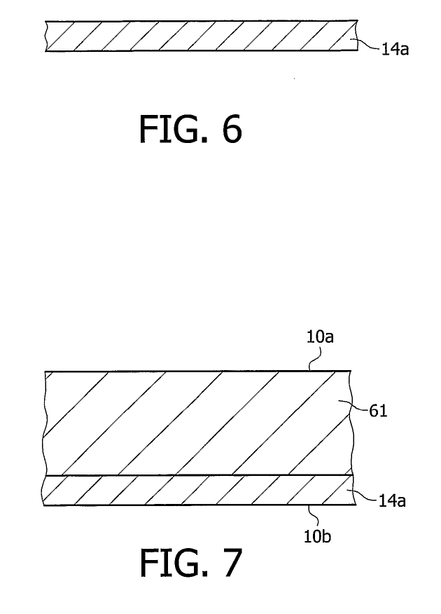

FIGS. 6 and 7 are cross-sectional views of a semiconductor body at two successive stages in the manufacture of a device according to embodiments of the invention.

It should be noted that the Figures are diagrammatic and not drawn to scale. Relative dimensions and proportions of parts of these Figures have been shown exaggerated or reduced in size, for the sake of clarity and convenience in the drawings. The same reference signs are generally used to refer to corresponding or similar features in modified and different embodiments.

FIG. 1 illustrates an exemplary embodiment of a power semiconductor field effect transistor device having a trench-gate 11. In the transistor cell areas of this device, source and drain regions, 13 and 14, 14a respectively, of a first conductivity type (n-type in this example) are separated by a channel-accommodating body region 15 of the opposite, second conductivity type (that is, p-type in this example).

The drain region comprises a low doped drift region 14 adjacent to a drain contact region 14a.

The gate 11 is present in a trench 20 which extends through the source and channel-accommodating regions 13 and 15 into an underlying portion drift region 14. The gate is insulated from the semiconductor body by an insulating layer 17. A capping layer 18 of silicon dioxide is provided over the gate 11.

The source region 13 is contacted by a source electrode 23 at the top major surface 10a of the semiconductor body 10. The drain contact region 14a is contacted at the bottom major surface 10b of the device body by the drain electrode 24.

The application of a voltage signal to the gate 11 in the on-state of the device serves in a known manner for inducing a conduction channel 12 in the region 15 and for controlling current flow in this conduction channel 12 between the source and drain regions 13 and 14,14a.

No plan view of the cellular layout geometry is shown in the drawings, because the configurations and methods described herein may be used for quite different, known cell geometries. Thus, for example, the cells may have a square geometry, or they have a close-packed hexagonal geometry or an elongate stripe geometry. In each case, the trench 20 (with its gate 11) extends around the boundary of each cell. FIG. 1 shows only a few cells, but typically the device comprises many hundreds of these parallel cells between the electrodes 23 and 24. The active cellular area of the device may be bounded around the periphery of the body 10 by various known peripheral termination schemes (also not shown). Such schemes normally include the formation of a thick field-oxide layer at the peripheral area of the body surface 10a, before the transistor cell fabrication steps. Furthermore, various known circuits (such as gate-control circuits) may be integrated with the device in an area of the body 10, between the active cellular area and the peripheral termination scheme. Typically their circuit elements may be fabricated with their own layout in this circuit area using some of the same masking and doping steps as are used for the transistor cells.

The doping concentration of the drift region 14 decreases substantially exponentially from its interface 19 with the drain contact region 14a to its interface 21 with the channel-accommodating region 15.

The embodiment shown in FIG. 2a differs from that of FIG. 1 in that a portion 17a of the gate insulating layer 17 across the base of the trench 20, between the gate and the drain drift region 14, is thicker than the remainder of the gate insulating layer, which extends over the side walls of the trench, and between the gate and the channel-accommodating region 15.

FIG. 2b shows a further trench-gate embodiment, in which the trench extends most of the way across the drift region 14 towards the drain contact region 14a. The gate electrode is extended into this deeper trench to form a field plate 37. The gate insulating layer 17 is thicker around this field plate extension than between the gate electrode and the channel-accommodating region.

The field plate per se is known in the art and serves to create a RESURF effect. This effect is enhanced in accordance with the invention by the presence of an exponential doping profile in the drain drift region 14.

A known vertical DMOS device configuration is shown in FIG. 3. It comprises a planar gate 31 provided over the top major surface 10a of the semiconductor body 10. The gate is surrounded by an insulating layer 33. According to the invention, the doping profile of the drain drift region 14 decreases substantially exponentially from its interface 19 with the drain contact region 14a to its interface 21 with the channel-accommodating portion 15 of p-type region 35.

The graph shown in FIG. 4 shows three different doping profiles. Doping concentration is plotted over a logarithmic scale on the y-axis against depth into a silicon semiconductor body from its top major surface (along a linear scale) on the x-axis.

Plot 43, marked by triangular data points, represents that of a device having a known, uniformly graded drain drift region; profile 45, plotted by circular data points, represents a known linearly graded type of profile; and profile 41, plotted using square data points, represents an exponentially graded drift doping profile according to an embodiment of the invention. Owing to the logarithmic scale of the y-axis, it can be seen that exponential profile 41 is represented by a straight line over the portion of the drain drift region between the depths of around 1.2 to 3.5 microns. In the example shown, the source region extends on the top major surface to a depth of around 0.3 microns, the channel-accommodating region from the source region to a depth of around 1 micron, the drain drift region from 1 micron to around 3.7 microns, and the drain contact region from 3.7 to 4.5 microns into the semiconductor body from its top major surface.

It can be seen that the drain drift region doping profile deviates from the exponential profile represented by a straight line in FIG. 4 towards each end of the region, where there is a transition region with the adjacent portion of the semiconductor body. Nevertheless, the profile is essentially exponential across the bulk, substantially the whole depth of the drain drift region.

FIG. 5 represents schematically the variation of doping level with depth in a trenchFET embodying the invention. Depth d represents the depth of the gate trench into the semiconductor body from its top major surface. A known uniform drain drift region doping profile is represented by line 51. With doping concentration shown on a logarithmic vertical scale, an exponential doping profile is represented by an inclined straight line 53. Profile 53 extends from a minimum doping concentration, N₀ at the interface with the channel-accommodating, p-body region, to a maximum Nₛ at the interface with the drain contact region.

The preferred values for N₀ and Nₛ, depend on a number of device parameters. In particular, the doping levels are dependent on the channel-accommodating region doping concentration and profile. It has been found that a higher gradient of the profile 53 shown in FIG. 5 yields improved results.

In the embodiment shown in FIG. 5, the channel-accommodating region has a uniform doping profile. In trials with such a configuration having a channel-accommodating region doping concentration of 1.8×10¹⁷ atoms/cm³, the preferred value for N₀ is in the range 0.95 to 1.2×10¹⁶ atoms/cm³. Nₛ is preferably greater than 20×10¹⁶ atoms/cm³ in this example. The thickness of the drift region was in the range 3.8 to 4.6 microns.

For devices designed to have a breakdown voltage in the range 25 to 30 volts, it is preferable for N₀ to be in the range 1 to 1.5×10¹⁶ atoms/cm³, with Nₛ greater than 20×10¹⁶ atoms/cm³. For devices having a breakdown voltage of 40 volts or more, N₀ is preferably around 0.5×10¹⁶ atoms/cm³, with Nₛ greater than 20×10¹⁶ atoms/cm³.

Embodiments of methods of manufacturing devices according to the present invention will now be described with reference to FIGS. 6 and 7.

In each embodiment, a substrate is provided, which forms the drain contact region 14a, as shown in FIG. 6. Subsequently, a semiconductor layer 61 is deposited epitaxially on substrate 14a, as shown in FIG. 7. The upper surface of layer 61 defines the top major surface 10a of the device, whilst the bottom surface of substrate 14a defines the bottom major surface 10b. Formation of a drain drift region having a substantially exponential doping profile within layer 61 will be discussed further below. It will be appreciated that other device features, such as those in the finished devices illustrated in FIGS. 1 to 3 may be formed in or on the structure shown in FIG. 7 using processing techniques well known in the art.

In one embodiment, substrate 14a is doped with phosphorus atoms at a concentration of 4.8×10¹⁹ atoms/cm³. The concentration may be up to 7.5×10¹⁹ atoms/cm³ or more. The layer 61 deposited thereon is doped uniformly at a relatively very low level, around 1×10¹⁵ atoms/cm³, with another n-type dopant having a lower diffusion coefficient than that of phosphorus, such as arsenic for example. During subsequent processing to form the device, layers 14a and 61 are heated. The thermal budget of this processing causes phosphorus atoms to diffuse out of the drain contact region 14a into layer 61, forming an exponential doping profile in layer 61, decreasing from the interface with layer 14a.

In another embodiment, layer 61 is not uniformly doped. Instead, the exponential layer growth process is controlled to produce a doping profile which, in combination with out-diffusion from layer 14a during processing, results in a finished device having the desired substantially exponential profile in its drain drift region.

In a further embodiment, substrate 14a is doped with a dopant such as arsenic, for example, with a relatively low diffusion coefficient (compared to phosphorus) so that negligible out-diffusion from the substrate occurs during processing. The layer 61 is then epitaxially deposited on the substrate, the doping of layer 61 being controlled during the deposition process so as to create the desired substantially exponential doping profile in the drain drift region of the finished device.

The particular examples described above in relation to FIGS. 1 to 3 are n-channel devices, in which the regions 13, 14 and 14a are of n-type conductivity, the region 15 is of p-type, and an electron inversion channel 12 is induced in the region 15 by the gate 11. By using opposite conductivity type dopants, a p-channel device can be manufactured by a method in accordance with the invention. In this case the regions 13, 14 and 14a are of p-type conductivity, the region 15 is of n-type, and a whole inversion channel 12 is induced in the region 15 by the gate 11.

Vertical discrete devices have been illustrated with reference to FIGS. 1-3, having a second main electrode 24 contacting the region 14a at the back surface 10b of the body 10. However, an integrated device is also possible in accordance with the invention. In this case, the region 14a may be a doped buried layer between a device substrate and the epitaxial low-doped drain drift region 14. This buried layer region 14a may be contacted by electrode 24 at the front major surface 10a, via a doped peripheral contact region which extends from the surface 10a to the depth of the buried layer.

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this Application to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present Application or of any further Application derived therefrom.

1. A semiconductor device including a semiconductor body, the semiconductor body comprising source and drain regions of a first conductivity type, and a channel-accommodating region of a second, opposite conductivity type which separates the source and drain regions, the device further comprising a gate which extends adjacent respective portions of the source, drain and channel-accommodating regions and is separated therefrom by a gate insulating layer wherein the drain region comprises a drain contact region and a drain drift region the drain drift region having a doping profile which decreases substantially exponentially from its interface with the drain contact region to its interface with the channel-accommodating region.

2. A device of claim 1 wherein the doping of the drain drift region at a distance X from the channel-accommodating region is approximately equal to A^{BX}, where A and B are constants.

3. A device of claim 1 wherein the drain contact and drift regions are doped with phosphorus atoms.

4. A device of claim 1 wherein a portion of the gate insulating layer between the gate and the drain drift region is thicker than a portion between the gate and the channel-accommodating region.

5. A device of claim 1 including field shaping means which extends adjacent the drain drift region, and is separated therefrom by an insulating layer.

6. A method of manufacturing a semiconductor device of claim 1 wherein the thermal budget of processing of the device causes dopant to diffuse out of the drain contact region into the drain drift region to form said doping profile in the drain drift region.

7. A method of claim 6 wherein prior to said out-diffusion the drain drift region is substantially uniformly doped, at a low level relative to that of the drain contact region.

8. A method of claim 6 wherein prior to said out-diffusion the drain contact region comprises phosphorus atoms at a concentration around or greater than 4.8×10¹⁹ atoms/cm³.

9. A method of manufacturing a semiconductor device of any of claim 1, the method including the steps of providing a semiconductor body comprising a highly doped drain contact region and forming thereon by epitaxial growth a layer having a doping profile which decreases substantially exponentially from its interface with the drain contact region to its top surface.
